(19) United States
(12) Patent Application Publication
(10) Pub. No.: US 2025/0192784 A1
(43) Pub. Date: Jun. 12, 2025

(54) DUAL-EDGE-TRIGGERED FLIP-FLOPS INCLUDING SCAN, RESET, AND DATA RETENTION FEATURES

(71) Applicant: QUALCOMM Incorporated, San Diego, CA (US)

(72) Inventors: Yimai PENG, Cary, NC (US); Robert Joseph VACHON, Zebulon, NC (US); Daniel YINGLING, Apex, NC (US); Keith Alan BOWMAN, Morrisville, NC (US)

(21) Appl. No.: 18/537,551

(22) Filed: Dec. 12, 2023

(51) Int. Cl. H03K 19/094; H03K 3/012; H03K 19/096; H03K 19/173

(52) U.S. Cl. CPC H03K 19/09425; H03K 3/012; H03K 19/0963; H03K 19/1737

(57) ABSTRACT

An apparatus, including: a first multiplexer including inputs configured to receive an input data signal and a scan signal, and a select input configured to receive shift control signal; a first latch including an input coupled to an output of the first multiplexer, and a complementary (e.g., inverting) clock input configured to receive a clock signal; a second latch including an input coupled to the output of the first multiplexer, and a non-complementary clock input configured to receive the clock signal; and a second multiplexer including inputs coupled to outputs of the first and second latches, respectively, a select input configured to receive the clock signal, and an output configured to generate an output data or scan signal.

### FIELD

Aspects of the present disclosure relate generally to data processing circuits, and in particular, to a dual-edge-triggered (DET) flip-flop (FF) including scan, reset, and data retention features.

### BACKGROUND

Functional circuits, such as processors, memory, and others, typically include sequential circuits, such as a network of cascaded and parallel flip-flops, driven by clock signals to move data from inputs, to functional subsystems or cores, and to outputs. Such sequential circuits may include design-for-testability (DFT) features including scan, reset, and data retention to input and output scan vectors to and from sequential circuits. Another feature that may be desirable for sequential circuits is to reset their outputs to known values to ensure proper start-up of such circuits. Further, an additional feature that may be provided to sequential circuits includes data retention of the current states of the sequential circuits during power gating intervals.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an apparatus. The apparatus includes a first multiplexer including inputs configured to receive an input data signal and a scan signal, and a select input configured to receive shift control signal; a first latch including an input coupled to an output of the first multiplexer, and a complementary clock input configured to receive a clock signal; a second latch including an input coupled to the output of the first multiplexer, and a non-complementary clock input configured to receive the clock signal; and a second multiplexer including inputs coupled to outputs of the first and second latches, respectively, a select input configured to receive the clock signal, and an output configured to generate an output data or scan signal.

Another aspect of the disclosure relates to a method. The method includes outputting a data signal or a scan signal based on a shift control signal; sequentially propagating the outputted data signal or scan signal to first and second nodes in response to rising and falling edges of a clock signal, respectively; and sequentially propagating the data signal or the scan signal at the first and second nodes to a third node based on the rising and falling edges of the clock signal, respectively.

Another aspect of the disclosure relates to an apparatus. The apparatus includes a first latch including an input configured to receive an input data signal, and a complementary clock input configured to receive a clock signal; a second latch including an input configured to receive the input data signal, and a non-complementary clock input configured to receive the clock signal; a multiplexer including inputs coupled to outputs of the first and second latch, respectively, and an output configured to generate an output data signal; and a first data retention (DR) latch configured to: store a value of the output data signal at the output of the multiplexer in response to a first control signal; and restore the value of the output data signal to the output of the multiplexer in response to a second control signal.

Another aspect of the disclosure relates to a method. The method includes: sequentially propagating a data signal to first and second nodes in response to rising and falling edges of a clock signal, respectively; sequentially propagating the data signal at the first and second nodes to a third node based on the rising and falling edges of the clock signal, respectively; retaining a value of the data signal at the third node in response to a first control signal; and restoring the value of the data signal at the third node in response to a second control signal.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example data processing circuit in accordance with an aspect of the disclosure.

FIG. 2 illustrates a block diagram of an example dual-edge-triggered (DET) flip-flop (FF) including scan and reset features in accordance with another aspect of the disclosure.

FIG. 3 illustrates a schematic diagram of an example dual-edge-triggered (DET) flip-flop (FF) including scan and reset features in accordance with another aspect of the disclosure.

FIG. 4 illustrates a schematic diagram of another example dual-edge-triggered (DET) flip-flop (FF) including scan and reset features in accordance with another aspect of the disclosure.

FIG. 5 illustrates a block diagram of another example data processing circuit in accordance with another aspect of the disclosure.

FIG. 6 illustrates a block diagram of an example dual-edge-triggered (DET) flip-flop (FF) including data retention feature in accordance with another aspect of the disclosure.

FIG. 7 illustrates a block diagram of another example dual-edge-triggered (DET) flip-flop (FF) including data retention feature in accordance with another aspect of the disclosure.

FIG. 8 illustrates a schematic diagram of another example dual-edge-triggered (DET) flip-flop (FF) including data retention feature in accordance with another aspect of the disclosure.

FIGS. 9A-9F illustrate the example dual-edge-triggered (DET) flip-flop (FF) of FIG. 8 in various configurations in accordance with another aspect of the disclosure.

FIG. 10 illustrates a schematic diagram of another example dual-edge-triggered (DET) flip-flop (FF) including data retention feature in accordance with another aspect of the disclosure.

FIG. 11 illustrates a flow diagram of an example method of propagating a selected data or scan signal in accordance with another aspect of the disclosure.

FIG. 12 illustrates a flow diagram of an example method of storing and restoring a value of a data signal at an output of a dual-edge-triggered (DET) flip-flop (FF) in accordance with another aspect of the disclosure.

FIG. 13 illustrates a block diagram of an example wireless communication device in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

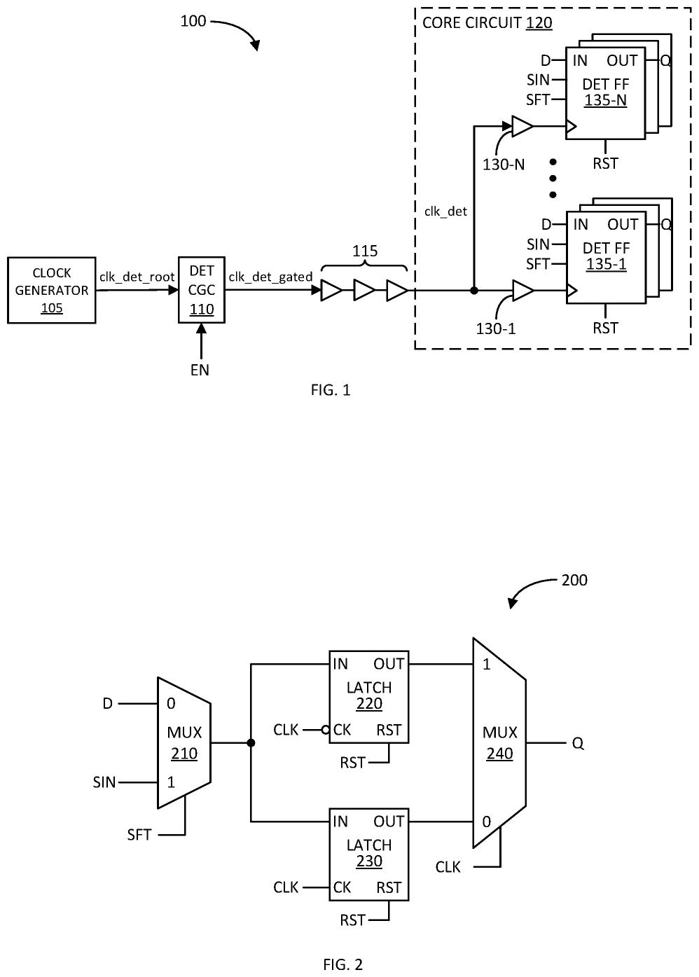

FIG. 1 illustrates a block diagram of an example data processing circuit 100 in accordance with an aspect of the disclosure. The data processing circuit 100 may be implemented in an integrated circuit (IC), such as a system on chip (SOC). It shall be understood that the data processing circuit 100 is merely an example, and many variations with same and/or different components are contemplated.

In particular, the data processing circuit 100 includes a clock generator (e.g., including a phase locked loop (PLL)) 105, a dual-edge-triggered (DET) clock gating circuit (CGC) 110, a set of one or more cascaded buffers 115, and a core circuit 120 (e.g., a processor, a central processing unit (CPU), a graphics processing unit (GPU), a digital signal processor (DSP), a memory (e.g., dynamic random access memory (DRAM)), etc.). The core circuit 120, in turn, includes a set of input buffers 130-1 to 130-N, and a set of DET flip-flops (FFs) 135-1 to 135-N.

The clock generator 105 is configured to generate a root DET clock signal clk_det_root. A clock signal, as defined herein, is a substantially periodic voltage waveform (e.g., substantially square wave) used to sequentially control the movement of data within a core circuit, such as core circuit 120. The root det clock signal clk_det_root may have a frequency for driving DET sequential circuits. The DET clock gating circuit (CGC) 110 is configured to gate/pass the root DET clock signal clk_det_root to generate a gated DET clock signal clk_det_gated based on an enable signal (EN) for power gating purposes. For example, if the enable signal (EN) is asserted (e.g., a logic one (1) or high voltage level), the DET clock gating circuit (CGC) 110 allows the root DET clock signal clk_det_root to pass as the gated DET clock signal clk_det_gated. If the enable signal (EN) is not asserted (e.g., a logic zero (0) or low voltage level), the DET clock gating circuit (CGC) 110 gates the root DET clock signal clk_det_root from passing therethrough. It shall be understood that the data processing circuit 100 may include more DET clock gating circuits (CGC) downstream of the DET clock gating circuit (CGC) 110.

The set of one or more cascaded buffers 115 provides isolation between the DET clock gating circuit (CGC) 110 and the core circuit 120. In this regard, the set of one or more cascaded buffers 115 generate a clock signal clk_det based on the gated clock signal clk_det_gated. The clock signal clk_det may be provided to clock inputs of the set of DET FFs 135-1 to 135-N-1 via the set of input buffers 130-1 to 130-N-1, respectively. Each of the set of DET FFs 135-1 to 135-N, which may include parallel DET FFs or a network of DET FFs, may pertain to a set of functional data pipelines for moving/routing input data (D) and output data (Q) to and/or from functional blocks (e.g., combinational logic, arithmetic logic units (ALUs), registers, etc.) as part of the core circuit 120.

For design-for-testability (DFT) purposes, each of the set of DET FFs 135-1 to 135-N includes a scan input (SIN), a shift input (SFT), and a reset input (RST). The SIN input is configured to receive a scan signal (also referred to as “SIN”) for propagating a scan signal via a set of scan pipelines for DFT purposes. The SFT input is configured to receive a shift control signal (also referred to as “SFT”) for configuring the set of DET FFs 135-1 to 135-N in DFT mode when the SFT signal is asserted (e.g., a logic one (1)), where each of the set of DET FFs 135-1 to 135-N clocks the scan signal at its SIN input to its output Q; and configuring the set of DET FFs 135-1 to 135-N in functional mode when the SFT signal is deasserted (e.g., a logic zero (0)), where each of the set of DET FFs 135-1 to 135-N clocks the data signal at its data (D) input to its respective output Q. The RST input is configured to receive a reset signal (also referred to as “RST”) for setting the corresponding output Q to a logic zero (0) and all DET FF internal nodes to be known values. This may be done prior to commencing a DFT procedure or functional operation, or at any other time as specified.

FIG. 2 illustrates a block diagram of an example dual-edge-triggered (DET) flip-flop (FF) 200 including scan and reset features in accordance with another aspect of the disclosure. The DET FF 200 may be an example implementation of any of the set of DET FFs 135-1 to 135-N of data processing circuit 100. The DET FF 200 includes an input multiplexer 210, a first latch 220, a second latch 230, and an output multiplexer 240.

The input multiplexer includes a first “0” input configured to receive an input data signal (D), a second input “1” configured to receive a scan (SIN) signal, and a select input configured to receive a shift (SFT) control signal. The first latch 220 includes an input coupled to an output of the input multiplexer 210, a complementary (e.g., inverting) clock input (CK) configured to receive a clock signal (CLK), a reset (RST) input configured to receive a reset signal, and an output coupled to a first “1” input of the output multiplexer 240.

The second latch 230 includes an input coupled to the output of the input multiplexer 210, a noncomplementary clock input (CK) configured to receive the clock signal (CLK), a reset (RST) input configured to receive the reset signal, and an output coupled to a second “O” input of the output multiplexer 240. The output multiplexer 240 includes a select input configured to receive the clock signal (CLK). The output multiplexer 240 includes an output (Q) configured to generate an output data signal. Note that the first and second latches 220 and 230 are coupled in parallel between the input multiplexer 210 and the output multiplexer 240. Further, the clock input of the first latch 220 is shown with the complementary signal compared to the clock input of the second latch 230 to signify that at a particular phase of the clock signal CLK, the first latch 220 may be in an opaque configuration and the second latch 230 may be in a transparent configuration; and at an opposite phase of the clock signal CLK, the first latch 220 may be in the transparent configuration and the second latch 230 may be in the opaque configuration.

The input multiplexer 210 is configured to output the data signal or the scan signal based on the shift control signal. For example, if the shift signal is asserted (e.g., a logic one (1)), the input multiplexer 210 outputs the scan signal for further propagation through the latches 220 and 230, and the output multiplexer 240. If the shift signal is deasserted (e.g., a logic zero (0)), the input multiplexer 210 outputs the data signal for further propagation through the latches 220 and 230, and the output multiplexer 240.

In the case where the reset signal is deasserted (e.g., a logic zero (0)), the first and second latches 220 and 230 sequentially propagate the selected signal (scan or data) to the outputs (nodes) of the latches 220 and 230 in response to rising and falling edges of the clock signal CLK, respectively. Similarly, the output multiplexer 240 sequentially propagates the selected signal (scan or data) at the outputs (nodes) of the latches 220 and 230 to the output (node) of the output multiplexer 240 in response to the rising and falling edges of the clock signal, respectively. In the case where the reset signal is asserted (e.g., a logic one (1)), the first and second latches 220 and 230 are configured to output known values (e.g., logic zeros (0s)) to set the output (Q) of the output multiplexer 240 to logic zero (0) in response to any edge of the clock signal.

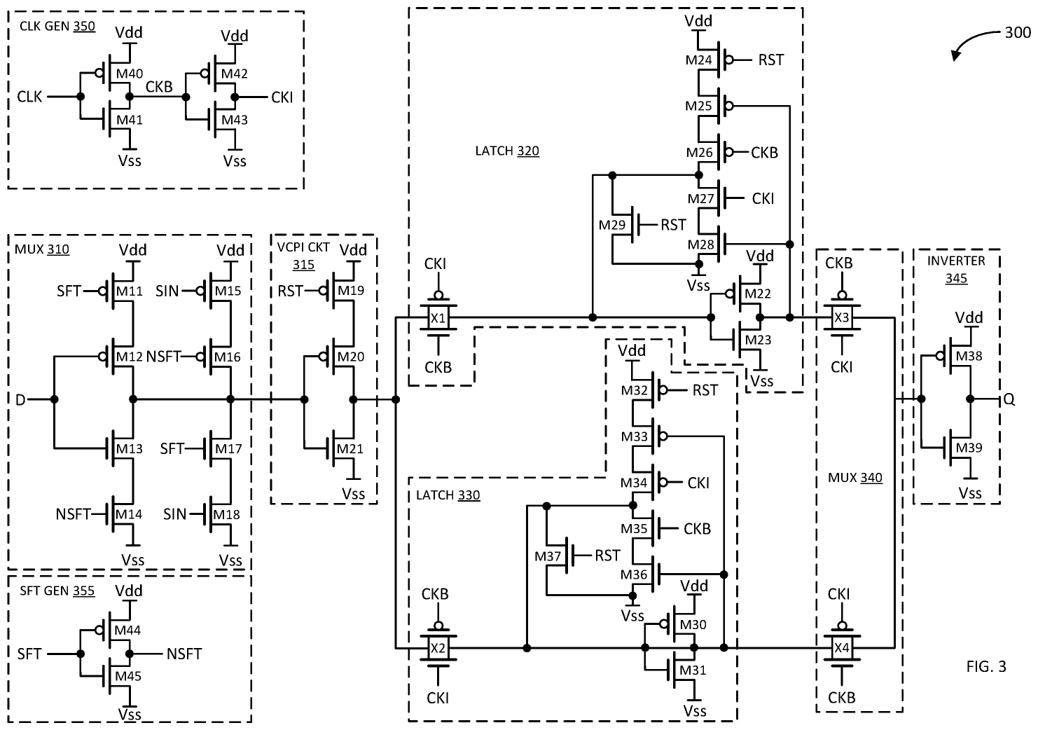

FIG. 3 illustrates a schematic diagram of another example dual-edge-triggered (DET) flip-flop (FF) 300 including scan and reset features in accordance with another aspect of the disclosure. The DET FF 300 may be an example implementation of the DET FF 200. In particular, the DET FF 300 includes an input multiplexer 310, a voltage contention prevention inverter (VCPI) circuit 315, a first latch 320, a second latch 330, an output multiplexer 340, an output inverter 345, a clock generation circuit 350, and a shift signal generation circuit 355.

The input multiplexer 310 includes a first set of field effect transistors (FETs) M11, M12, M13, and M14 coupled in series, via their respective source/drain and drain/source terminals, between an upper voltage rail Vdd and a lower voltage rail Vss (e.g., ground). The FETs M11 and M12 may be implemented as p-channel FETs, and the FETs M13 and M14 may be implemented as n-channel FETs. The FET M11 includes a gate configured to receive the shift (SFT) control signal. The FETs M12 and M13 include gates coupled together, and serving as a first “0” input of the input multiplexer 310 to receive the data (D) signal. The FET M14 includes a gate configured to receive a complementary shift (NSFT) control signal. In this regard, the shift signal generation circuit 355 includes an inverter M44/M45 configured to receive and invert the shift (SFT) signal to generate the complementary shift (NSFT) signal. The term inverter MX/MY, as used herein, is a short way to specify that the inverter includes a p-channel FET MX coupled in series with an n-channel FET MY between upper and lower voltage rails Vdd and Vss, with gates coupled together serving as an input of the inverter, and drains coupled together serving as an output of the inverter.

The input multiplexer 310 further includes a second set of FETs M15, M16, M17, and M18 coupled in series, via their respective source/drain and drain/source terminals, between the upper voltage rail Vdd and the lower voltage rail Vss. The FETs M15 and M16 may be implemented as p-channel FETs, and the FETs M17 and M18 may be implemented as n-channel FETs. The FETs M15 and M18 include gates serving as the second “1” input of the input multiplexer 310 to receive the scan (SIN) signal. The FET M16 includes a gate configured to receive the complementary shift signal NSFT. The FET M17 includes a gate configured to receive the shift signal SFT. The FETs M12, M13, M16, and M17 include drains coupled together and serving as the output of the input multiplexer 310 to output the selected data (D) or scan (SIN) signal.

In operation with regard to the input multiplexer 310, if the shift (SFT) signal is asserted (e.g., a logic one (1) for the SFT signal and a logic zero (0) for the NSFT signal), the FETs M11 and M14 are turned off, and the FETs M16 and M17 are turned on. Thus, the scan signal SIN is allowed to propagate to the output of the input multiplexer 310 via turned-on FETs M16 and M17, while the disabled inverter M12/M13 blocks the data (D) signal from propagating to the output. If the shift signal SFT is deasserted (e.g., a logic zero (0) for the SFT signal and a logic one (1) for the NSFT signal), the FETs M11 and M14 are turned on, and the FETs M16 and M17 are turned off. Thus, the data (D) signal is allowed to propagate to the output of the input multiplexer 310 via the enabled inverter M12/M13, while the turned-off FETs M16 and M17 block the scan signal from propagating to the output.

As explained in more detail further herein, the voltage contention prevention inverter circuit 315 is configured to isolate the output of the input multiplexer 310 from the common input of the first and second latches 320 and 330 during a reset interval. For example, the common input may be set to a known value (e.g., Vss potential or a logic zero (0)) when the reset signal is asserted (e.g., a logic one (1)). The voltage contention prevention inverter circuit 315 isolates the output of the input multiplexer 310, which could be a logic one (1) or a logic zero (0), from the known value (e.g., a logic zero (0)) at common input of the latches 320 and 330 during a reset interval.

In particular, the voltage contention prevention inverter circuit 315 may be implemented as a half tristate inverter. That is, the voltage contention prevention inverter circuit 315 includes a set of FETs M19, M20, and M21 coupled in series, via their respective source/drain and drain/source terminals, between the upper voltage rail Vdd and the lower voltage rail Vss. The FETs M19 and M20 may be implemented as p-channel FETs, and the FET M21 may be implemented as an n-channel FET. The FET M19 includes a gate configured to receive the reset signal. The FETs M20 and M21, operating as an inverter when enabled, include gates coupled to the output of the input multiplexer 310, and drains coupled to the common input of the latches 320 and 330. When the reset signal is not asserted (e.g., a logic zero (0)), the FET M19 is turned on to enable the inverters M20/M21 as the common input of the latches 320 and 330 is dictated by the logic value at the output of the input multiplexer 310. When the reset signal is asserted (e.g., a logic one (1)), the FET M19 is turned off to disable the inverter M20/M21; and thereby, isolate the common input (e.g., at the known value) of the latches 320 and 330 from the output of the input multiplexer 310.

The first latch 320 includes a gating circuit, such as a transmission gate X1, an inverter M22/M23, and a tristate inverter M24-M28 including a reset associated FET M29. The transmission gate X1 is coupled in series with the inverter M22/M23 between the input and output of the first latch 320. The transmission gate X1 includes a complementary control input configured to receive a clock signal (CKI), and a non-complementary control input configured to receive a complementary clock signal (CKB). With regard to the clock signals, the DET FF 300 includes a clock generation circuit 350 configured to receive an input clock signal (CLK). The clock generation circuit 350 includes a set of cascaded inverters M40/M41 and M42/M43 configured to generate the complementary clock signal CKB and the clock signal CKI, respectively.

The tristate inverter M24-M28 is cross-coupled with the inverter M22/M23, meaning that the tristate inverter includes an input coupled to an output of the inverter, and the inverter includes an input coupled to an output of the tristate inverter. More specifically, the tristate inverter includes a set of FETs M24, M25, M26, M27, and M28 coupled in series, via their respective source/drain and drain/source terminals, between the upper voltage rail Vdd and the lower voltage rail Vss. The FETs M24, M25, and M26 may be implemented as p-channel FETs, and the FETs M26, M27, and M28 may be implemented as n-channel FETs. The FET M24 includes a gate configured to receive the reset signal. The FETs M25 and M28 include gates coupled to the output of the inverter M22/M23. The FET M26 includes a gate configured to receive the complementary clock signal CKB. And the FET M27 includes a gate configured to receive the clock signal CKI. The FET M29 is coupled between the output of the tristate inverter at the drains of FETs M26 and M27 and the lower voltage rail Vss. As mentioned, the output (drains of FETs M26 and M27) of the tristate inverter is also coupled to the input of the inverter M22/M23.

The second latch 330 includes a gating circuit, such as a transmission gate X2, an inverter M30/M31, and a tristate inverter M32-M36 including a reset associated FET M37. The transmission gate X2 is coupled in series with the inverter M30/M31 between the input and output of the second latch 330. The transmission gate X2 includes a complementary control input configured to receive the complementary clock signal CKB, and a non-complementary control input configured to receive the clock signal CKI.

The tristate inverter M32-M36 is cross-coupled with the inverter M30/M31. More specifically, the tristate inverter includes a set of FETs M32, M33, M34, M35, and M36 coupled in series, via their respective source/drain and drain/source terminals, between the upper voltage rail Vdd and the lower voltage rail Vss. The FETs M32, M33, and M34 may be implemented as p-channel FETs, and the FETs M35, M36, and M37 may be implemented as n-channel FETs. The FET M32 includes a gate configured to receive the reset signal. The FETs M33 and M36 include gates coupled to the output of the inverter M30/M31. The FET M34 includes a gate configured to receive the clock signal CKI. And the FET M35 includes a gate configured to receive the complementary clock signal CKB. The FET M37 is coupled between the output of the tristate inverter at the drains of FETs M34 and M35 and the lower voltage rail Vss. As mentioned, the output (drains of FETs M34 and M35) of the tristate inverter is also coupled to the input of the inverter M30/M31.

In the case where the reset signal is deasserted, the first and second latches 320 and 330 are collectively configured to sequentially propagate the data or scan signal from the output of the input multiplexer 310 to the inputs of the output multiplexer 340 in an alternating manner. For example, in response to a rising edge or a high phase of the clock signal CLK, the first latch 320 is in an opaque configuration to output the i^{th} bit of the data or scan signal, and the second latch 330 is in a transparent configuration to receive the (i+1)^{th} bit of the data or scan signal. In the opaque configuration of the first latch 320, the transmission gate X1 is off, and the cross-coupled inverter M22/M23 and tristate inverter M24-M28 is enabled; thereby latching the i^{th} bit of the data or scan signal at the first input of the output multiplexer 340. In the transparent configuration of the second latch 330, the transmission gate X2 is on to allow the (i+1)^{th} bit to pass to the disabled cross-coupled inverter M30/M31 and tristate inverter M32-M36.

In response to a falling edge or a low phase of the clock signal CLK, the first latch 320 is in the transparent configuration to receive the (i+2)^{th} bit of the data or scan signal, and the second latch 330 is in the opaque configuration to output the (i+1)^{th} bit of the data or scan signal. In the transparent configuration of the first latch 320, the transmission gate X1 is on to allow the (i+2)^{th} bit to pass to the disabled cross-coupled tristate inverter M24-M28 and inverter M22/M23. In the opaque configuration of the second latch 330, the transmission gate X2 is off, and the cross-coupled inverter M30/M31 and tristate inverter M32-M36 is enabled; thereby latching the (i+1)^{th} bit of the data or scan signal at the second input of the output multiplexer 340.

In response to the reset signal being asserted, the respective tristate inverters M24-M28 and M32-M36 of the first and second latches 320 and 330 are off, and the FETs M29 and M37 are turned on to apply Vss potential (e.g., a logic zero (0)) at the inputs of the inverters M22/M23 and M30/M31, respectively. Accordingly, the inverters M22/M23 and M30/M31 invert the logic zeros (0s) to generate logic ones (1s) at the first and second inputs of the output multiplexer 340, respectively. As both inputs are logic ones (1), the output multiplexer 340 outputs a logic one (1) regardless of the phase of the clock signal CLK. The output inverter 345 inverts the logic one (1) to generate a logic zero (0) (an example of a known value) at the output Q in response to the asserted reset signal.

The output multiplexer 340 includes transmission gates X3 and X4. The transmission gate X3 includes an input coupled to the output of the first latch 320, a complementary control input configured to receive the complementary clock signal CKB, and a non-complementary control input configured to receive the clock signal CKI. Similarly, the transmission gate X4 includes an input coupled to the output of the second latch 330, a complementary control input configured to receive the clock signal CKI, and a non-complementary control input configured to receive the complementary clock signal CKB.

Again, in the case the reset signal is deasserted, in response to a rising edge or high phase of the clock signal CLK, the transmission gate X3 is on and the transmission gate X4 is off. Accordingly, the output multiplexer 340 outputs the latched i^{th} bit from the opaque first latch 320, while blocking the (i+1)^{th} bit from the transparent second latch 330. In response to a falling edge or low phase of the clock signal CLK, the transmission gate X3 is off and the transmission gate X4 is on. Accordingly, the output multiplexer 340 outputs the latched (i+1)^{th} bit from the opaque second latch 330, while blocking the (i+2)^{th} bit from the transparent first latch 320. The output inverter 345 or M38/M39 includes an input coupled to the output of the output multiplexer 340, and an output Q to generate an output data or scan signal. The output inverter 345 may serve to logically make the output data or scan signal and the input data or scan signal the same value.

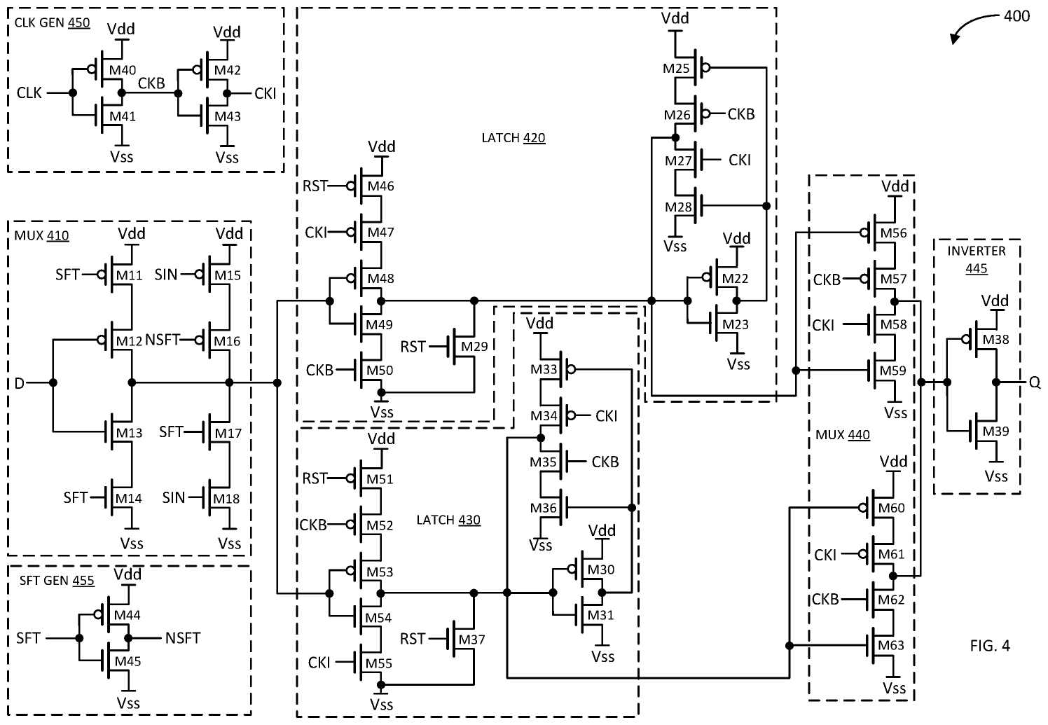

FIG. 4 illustrates a block diagram of another example dual-edge-triggered (DET) flip-flop (FF) 400 including scan and reset features in accordance with another aspect of the disclosure. The DET FF 400 may be another example implementation of the DET FF 200. Additionally, the DET FF 400 may be a variation of the DET FF 300 previously discussed in detail, including many of the same/similar elements as indicated by the same reference numbers with the exception that their most significant digit is a “4” in the case of DET FF 400 instead of a “3” in the case of DET FF 300. Further, the FETs in DET FF 400 corresponding to the FETs in DET FF 300 are labeled the same to facilitate explanation.

The DET FF 400 differs from DET FF 300 in that: (1) DET FF 400 may not include the voltage contention prevention inverter circuit 315 of DET FF 300; (2) the transmission gates X1-X4 of DET FF 300 are replaced with tristate inverters M46-M50, M51-M55, M56-M59, and M60-M63 in DET FF 400, respectively; (3) the tristate inverters M25-M28 and M33-M36 of DET FF 400 do not include the reset signal associated FETs M24 and M32, respectively; and (4) the inputs (instead of the outputs) of the inverters M22/M23 and M30/M31 serve as the outputs of the first and second latches 420 and 430, and are coupled to the inputs of the output multiplexer 440 in DET FF 400, respectively.

The tristate inverter M46-M50 includes a set of FETs M46-M50 coupled in series, via their respective source/drain and drain/source terminals, between the upper voltage rail Vdd and the lower voltage rail Vss. The FETs M46-M48 may be implemented as p-channel FETs, and the FETs M49-M50 may be implemented as n-channel FETs. The FET M46 includes a gate configured to receive the reset signal. The FET M47 includes a gate configured to receive the clock signal CKI. The FETs M48 and M49 include gates coupled to the output of the input multiplexer 410. And, the FET M50 includes a gate configured to receive the complementary clock signal CKB.

Similarly, the tristate inverter M51-M55 includes a set of FETs M51-M55 coupled in series, via their respective source/drain and drain/source terminals, between the upper voltage rail Vdd and the lower voltage rail Vss. The FETs M51-M53 may be implemented as p-channel FETs, and the FETs M54-M55 may be implemented as n-channel FETs. The FET M51 includes a gate configured to receive the reset signal. The FET M52 includes a gate configured to receive the complementary clock signal CKB. The FETs M53 and M54 include gates coupled to the output of the input multiplexer 410. And, the FET M55 includes a gate configured to receive the clock signal CKI.

The tristate inverter M56-M59 includes a set of FETs M56-M59 coupled in series, via their respective source/drain and drain/source terminals, between the upper voltage rail Vdd and the lower voltage rail Vss. The FETs M56-M57 may be implemented as p-channel FETs, and the FETs M58-M59 may be implemented as n-channel FETs. The FETs M56 and M59 include gates coupled to the output of the first latch 420. The FET M57 includes a gate configured to receive the complementary clock signal CKB. The FET M58 includes a gate configured to receive the clock signal CKI.

Similarly, the tristate inverter M60-M63 includes a set of FETs M60-M63 coupled in series, via their respective source/drain and drain/source terminals, between the upper voltage rail Vdd and the lower voltage rail Vss. The FETs M60-M61 may be implemented as p-channel FETs, and the FETs M62-M63 may be implemented as n-channel FETs. The FETS M60 and M63 include gates coupled to the output of the second latch 430. The FET M61 includes a gate configured to receive the clock signal CKI. The FET M62 includes a gate configured to receive the complementary clock signal CKB.

The tristate inverters M46-M50, M51-M55, M56-M59, and M60-M64 operate similar to the transmission gates X1-X4 when the reset signal is deasserted. That is, the tristate inverter M46-M50 is off during the high phase of the clock signal CLK so that the first latch 420 is in the opaque configuration. The tristate inverter M51-M55 is on during the high phase of the clock signal CLK so that the second latch 430 is in the transparent configuration. The tristate inverter M56-M59 is on during the high phase of the clock signal CLK so that the output multiplexer 440 outputs the latched bit from the opaque first latch 420. The tristate inverter M60-M63 is off during the high phase of the clock signal CLK so that the output multiplexer 440 blocks the bit from the transparent second latch 430.

Similarly, the tristate inverter M46-M50 is on during the low phase of the clock signal CLK so that the first latch 420 is in the transparent configuration. The tristate inverter M51-M55 is off during the low phase of the clock signal CLK so that the second latch 430 is in the opaque configuration. The tristate inverter M56-M59 is off during the low phase of the clock signal CLK so that the output multiplexer 440 blocks the bit from the transparent first latch 420. The tristate inverter M60-M63 is on during the low phase of the clock signal CLK so that the output multiplexer 440 outputs the latched bit from the opaque second latch 430.

In the case where the reset signal is asserted, the tristate inverters M46-M50 and M51-M55 are off. The FETs M29 and M37 turn on in response to the asserted reset signal to apply Vss potential (e.g., a logic zero (0)) at the outputs of the first and second latches 420 and 430. And, as previously discussed, the output Q is set to a known value (e.g., a logic zero (0)) via the “inverting” output multiplexer 440 and the output inverter 445. The voltage contention prevention inverter circuit 315 is not needed in DET FF 400 because the disabled tristate inverters M46-M50 and M51-M55 isolate the known value (e.g., a logic zero (0)) at outputs of the first and second latches 420 and 430 from the output of the input multiplexer 410.

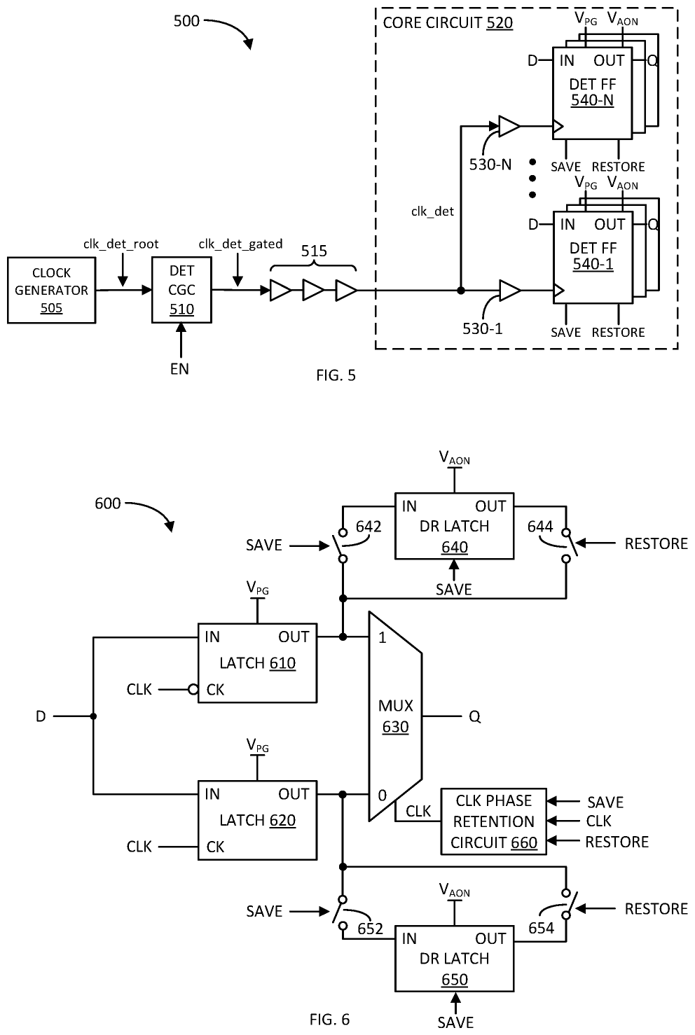

FIG. 5 illustrates a block diagram of another example data processing circuit 500 in accordance with another aspect of the disclosure. The data processing circuit 500 may be a variation or an addition to the data processing circuit 100 previously discussed. Accordingly, the data processing circuit 500 includes many of the same/similar elements as the data processing circuit 100 as identified by the same reference numbers with the exception that their most significant digit is a “5” in data processing circuit 500 instead of a “1” in data processing circuit 100.

The data processing circuit 500 differs from data processing circuit 100 in that the data processing circuit 500 includes a set of DET FFs 540-1 to 540-N with data retention feature. That is, for power saving purposes, the supply voltage V_{PG} applied to the set of DET FFs 540-1 to 540-N may be power gated to conserve power. More specifically, the supply voltage V_{PG} may be removed from the set of DET FFs 540-1 to 540-N during power gating intervals to reduce their power consumption. However, if the set of DET FFs 540-1 to 540-N do not have data retention feature, the output data retained by the set of DET FFs 540-1 to 540-N are not saved during power gating interval.

In this regard, the set of DET FFs 540-1 to 540-N are configured to receive data and restore signals. For example, prior to a power gating interval, the save signal is asserted to cause the output data in the set of DET FFs 540-1 to 540-N to be stored in associated data retention (DR) latch powered by an always-on supply voltage V_{AON}. Once the output data is stored, the power gating interval may commence. After the power gating interval has ended, the restore signal is asserted to cause the stored output data to be rewritten into outputs of the set of DET FFs 540-1 to 540-N. The following describes various implementations and associate modes of operations pursuant to the data retention feature.

FIG. 6 illustrates a block diagram of an example dual-edge-triggered (DET) flip-flop (FF) 600 including a data retention feature in accordance with another aspect of the disclosure. The DET FF 600 may be an example implementation of any of the set of DET FFs 540-1 to 540-N of data processing circuit 500 previously discussed. In particular, the DET FF 600 includes a first latch 610, a second latch 620, a multiplexer 630, a first data retention (DR) latch 640 including associated switching devices 642 and 644, and a second DR latch 650 including associated switching devices 652 and 654.

The first and second latches 610 and 620 include respective inputs configured to receive a data signal. The first and second latches 610 and 620 also include respective inputs configured to receive a clock signal CLK. The first and second latches 610 and 620 include respective outputs coupled to first “1” and second “0” inputs of the multiplexer 630, respectively. The first and second latches 610 and 620 are coupled to a power gating supply voltage rail V_{PG}. The multiplexer 630 includes a select input configured to receive the clock signal selectively gated by a clock phase retention circuit 660 based on a save signal and a restore signal, as discussed in more detail further herein. The multiplexer 630 includes an output configured to output an output data signal Q.

The first switching device 642, which is configured to receive a save signal, is coupled between the output of the first latch 610 and an input of the first DR latch 640. The second switching device 644, which is configured to receive a restore signal, is coupled between an output of the first DR latch 640 and the output of the first latch 610. The first DR latch 640 is powered by an always-on supply voltage V_{AON}, and is also configured to receive the save signal. Similarly, the second switching device 652, which is configured to receive the save signal, is coupled between the output of the second latch 620 and an input of the second DR latch 650. The second DR latch 650 is powered by the always-on supply voltage V_{AON}, and is also configured to receive the save signal. The second switching device 654, which is configured to receive the restore signal, is coupled between an output of the second DR latch 650 and the output of the second latch 620.

In operation, prior to a power gating interval, the save signal is asserted to close the first switching devices 642 and 652 so that the data at the output of the opaque first or second latch 610 or 620, which is the same (or inverted) as the data at the output Q, is provided to the input of the corresponding first or second DR latch 640 or 650. The asserted save signal also configures the first and second DR latches 640 and 650 in transparent configuration to receive the data. The data outputted by the transparent first or second latch 610 or 620 is not valid for data retention as it is not related to the data at the output Q. Also, in response to the asserted save signal, the clock phase retention circuit 660 stores the phase of the clock signal CLK to identify which of the first or second latch 610 or 620 is opaque. Then, the save signal is deasserted to open the first switching devices 642 and 652, and the first and second DR latches responsively become opaque to latch the data. The supply voltage V_{PG} provided to the first and second latches 610 and 620 may then be gated or removed during a power gating interval.

Once the power gating interval has ended, the supply voltage V_{PG} is provided to the first and second latches 610 and 620. Then the restore signal is asserted to close the second switching devices 644 and 654 to provide the latched data to the outputs of the first and second latches 610 and 620, respectively. If the phase of the clock signal CLK when the restore signal is asserted is the same as the stored phase of the clock signal CLK, then the clock phase retention circuit 660 outputs the clock signal CLK for the multiplexer 630. If the phase of the clock signal CLK when the restore signal is asserted is not the same as the stored phase of the clock signal CLK, then the clock phase retention circuit 660 waits until the phase of the clock signal CLK becomes the same as the stored phase, and then outputs the clock signal CLK for the multiplexer 630. In response to the clock signal, the data outputted by the opaque first or second latch 610 or 620 is provided to the output Q; and thereby, data retention of the output data is effectuated. The restore signal may then be deasserted to open the second switching devices 644 and 654.

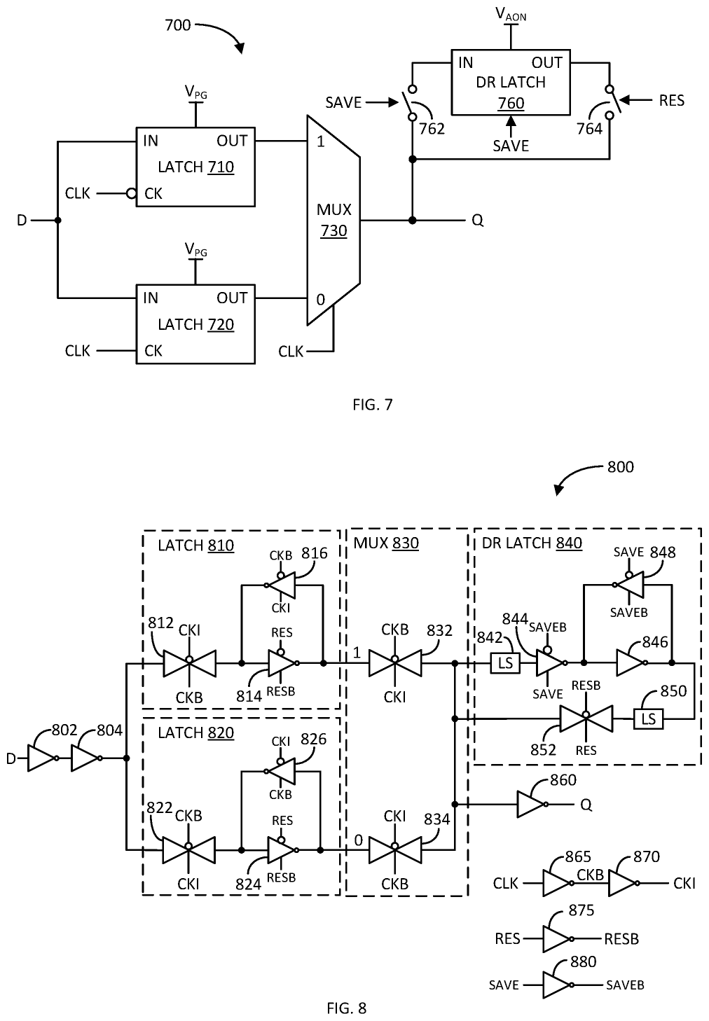

FIG. 7 illustrates a block diagram of another example dual-edge-triggered (DET) flip-flop (FF) 700 including a data retention feature in accordance with another aspect of the disclosure. The DET FF 700 may also be an example implementation of any of the set of DET FFs 540-1 to 540-N of data processing circuit 500 previously discussed. The DET FF 700 may be an alternative implementation of DET FF 600, and includes some of the same/similar elements as DET FF 700 as DET FF 600 as indicated by the same reference numbers with the exception that their most significant digit is a “7” for DET FF 700 instead of a “6” as in DET FF 600.

The DET FF 700 differs from DET FF 600 in that: (1) DET FF 700 may include one data retention (DR) latch 760 instead of two DR latches 640 and 650 in DET FF 600; (2) the DR latch 760 is coupled to the output of the multiplexer 730 instead of the inputs of the multiplexer 630; and (3) the DET FF 700 may not include the clock phase retention circuit 660 of DET FF 600. Thus, the DET FF 700 may have advantages over the DET FF 600, such as requiring less circuit footprint because only one DR latch is needed, power saving also because only one DR latch is needed, and it does not require tracking of the phase of the clock signal during save and restore operations.

The DET FF 700 includes a first switching device 762 coupled between the output of the multiplexer 730 and an input of the DR latch 760, and configured to receive the save signal. The DET FF 700 includes a second switching device 764 coupled between an output of the DR latch 760 and the output of the multiplexer 730, and configured to receive the restore (RES) signal. The second DR latch 760 is powered by the always-on supply voltage V_{AON}, and is also configured to receive the save signal.

In operation, prior to a power gating interval, the save signal is asserted to close the first switching device 762 so that the data at the output of the multiplexer 730 is provided to the input of the DR latch 760. The asserted save signal also configures the DR latch 760 in transparent configuration to receive the data. Then, the save signal is deasserted to open the first switching device 762, and the DR latch 760 responsively becomes opaque to latch the data. The supply voltage V_{PG} provided to the first and second latches 710 and 720 may then be gated or removed during a power gating interval. Once the power gating interval has ended, the supply voltage V_{PG} is provided to the first and second latches 710 and 720. Then the restore signal is asserted to close the second switching device 764 to provide the latched data to the output of the multiplexer 730 to effectuate the data retention. The restore signal may then be deasserted to open the second switching device 764.

FIG. 8 illustrates a block diagram of another example dual-edge-triggered (DET) flip-flop (FF) 800 including a data retention feature in accordance with another aspect of the disclosure. The DET FF 800 may be an example implementation of DET FF 700. The DET FF 800 is based on the DET FF 300. In particular, the DET FF 800 includes a buffer including one or more cascaded inverters 802 and 804, a first latch 810, a second latch 820, an output multiplexer 830, and a data retention (DR) latch 840. The buffer 802/804 is coupled between a data (D) input and the inputs of the first and second latches 810 and 820.

The first latch 810 includes a transmission gate 812, a first tristate inverter 814, and a second tristate inverter 816 cross-coupled with the first tristate inverter 814. The transmission gate 812 includes a complementary input configured to receive a clock signal CKI, and a non-complementary input configured to receive a complementary clock signal CKB. The DET FF 800 includes a clock generation circuit including cascaded inverters 865 and 870 configured to generate the complementary clock signal CKB and the clock signal CKI from an input clock signal CLK, respectively. The tristate inverter 814 includes a complementary input configured to receive a restore (RES) signal and a non-complementary input configured to receive a complementary restore signal RESB. The DET FF 800 includes at least one inverter 875 configured to generate the complementary restore signal RESB from the restore signal RES. The tristate inverter 816 includes a complementary input configured to receive the complementary clock signal CKB, and a non-complementary input configured to receive the clock signal CKI. The transmission gate 812 and the tristate inverter 814 are coupled in series between the input and output of the first latch 810.

The second latch 820 includes a transmission gate 822, a first tristate inverter 824, and a second tristate inverter 826 cross-coupled with the first tristate inverter 824. The transmission gate 822 includes a complementary input configured to receive the complementary clock signal CKB, and a non-complementary input configured to receive the clock signal CKI. The tristate inverter 824 includes a complementary input configured to receive the restore signal RES and a non-complementary input configured to receive the complementary restore signal RESB. The tristate inverter 826 includes a complementary input configured to receive the clock signal CKI, and a non-complementary input configured to receive the complementary clock signal CKB. The transmission gate 822 and the tristate inverter 824 are coupled in series between the input and output of the second latch 820. The multiplexer 820 includes inputs “1” and “0” coupled to the outputs of the first and second latches 810 and 820, respectively. The multiplexer 820 includes first and second transmission gates 832 and 834 coupled between the first “1” and second “0” inputs and the output of the multiplexer 830, respectively.

The DR latch 820 includes a first level shifter (LS) 842, a first tristate inverter 844, an inverter 846 cross-coupled with a second tristate inverter 848, a second LS 850, and a transmission gate 852 coupled in series in a roundabout manner beginning and ending at the output of the multiplexer 830. The first LS 842, including an input coupled to the output of the multiplexer 830, is configured to provide buffering/isolation and/or voltage level shifting between the output of the multiplexer 830 and the tristate inverter 844 as they may be on different voltage domains V_{PG} and V_{AON}, respectively. The tristate inverter 844 includes an input coupled to an output of the first LS 842, a complementary input configured to receive a complementary save signal SAVEB, and a non-complementary input configured to receive the save signal SAVE. In this regard, the DR latch 820 includes at least one inverter 880 configured to generate the complementary save signal SAVEB from the save signal SAVE.

The cross-coupled inverter 846 and second tristate inverter 848 are coupled between an output of the tristate inverter 844 and an input of the second LS 850. The second tristate inverter 848 includes a complementary input configured to receive the save signal SAVE, and a non-complementary input configured to receive the complementary save signal SAVEB. The second LS 850 also provides buffering/isolation and/or voltage level shifting between the cross-coupled inverter 846 and second tristate inverter 848 and the transmission gate 852 as they may be on different voltage domains V_{AON} and V_{PG}, respectively. The transmission gate 852, which is coupled between the second LS 850 and the output of the multiplexer 830, includes a complementary input configured to receive the complementary restore signal RESB and a non-complementary input configured to receive the restore signal RES.

As alluded to, the buffer 802/804, the first latch 810, the second latch 820, the multiplexer 830, the clock generating inverters 865 and 870, the restore signal related inverter 875, the second LS 850, and the transmission gate 852 may be in the Vpq voltage domain. Whereas, the first LS 842, the first tristate inverter 844, the cross-coupled inverter 846 and second tristate inverter 848, and the save signal related inverter 880 may be in the V_{AON} voltage domain. The following description describes a couple examples of save and restore operations performed by the DET FF 800.

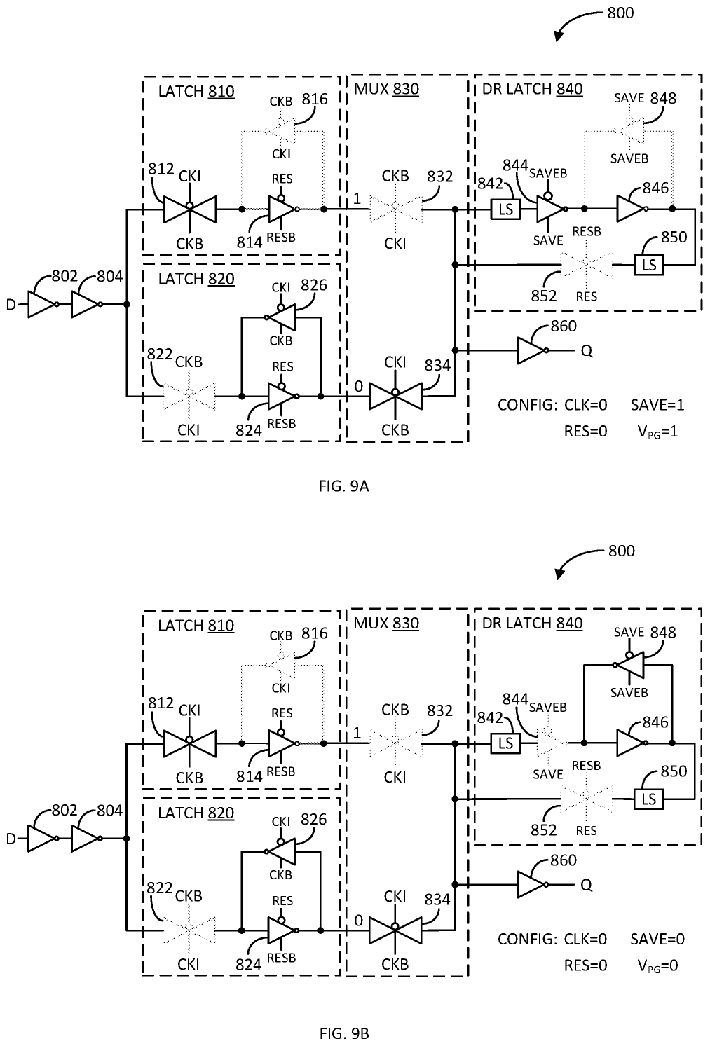

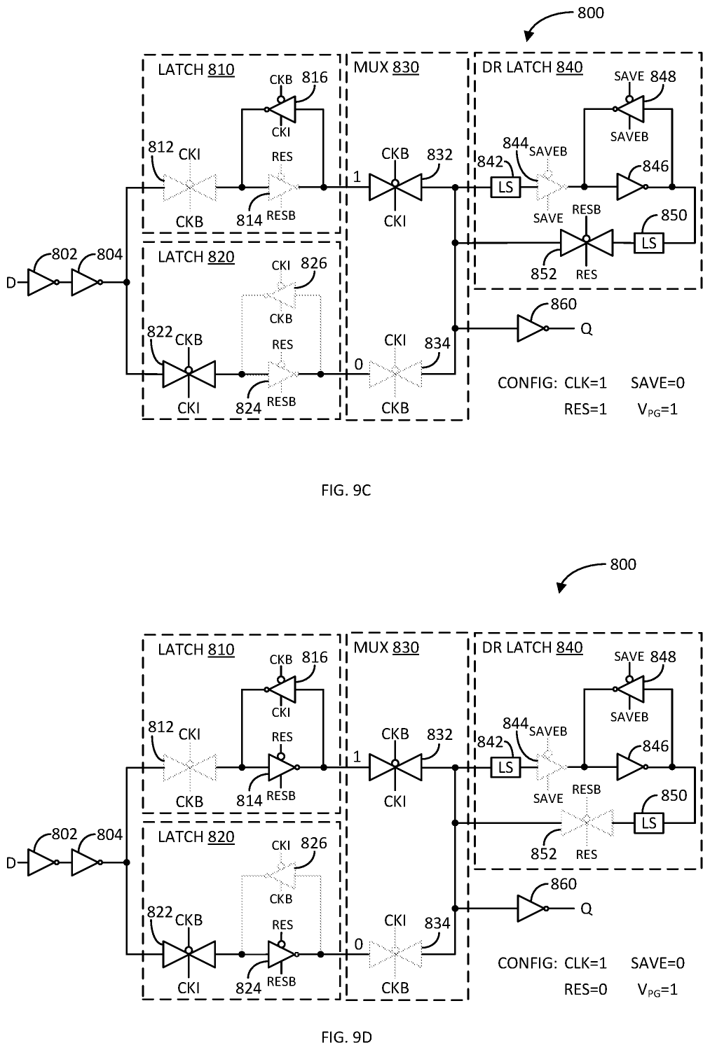

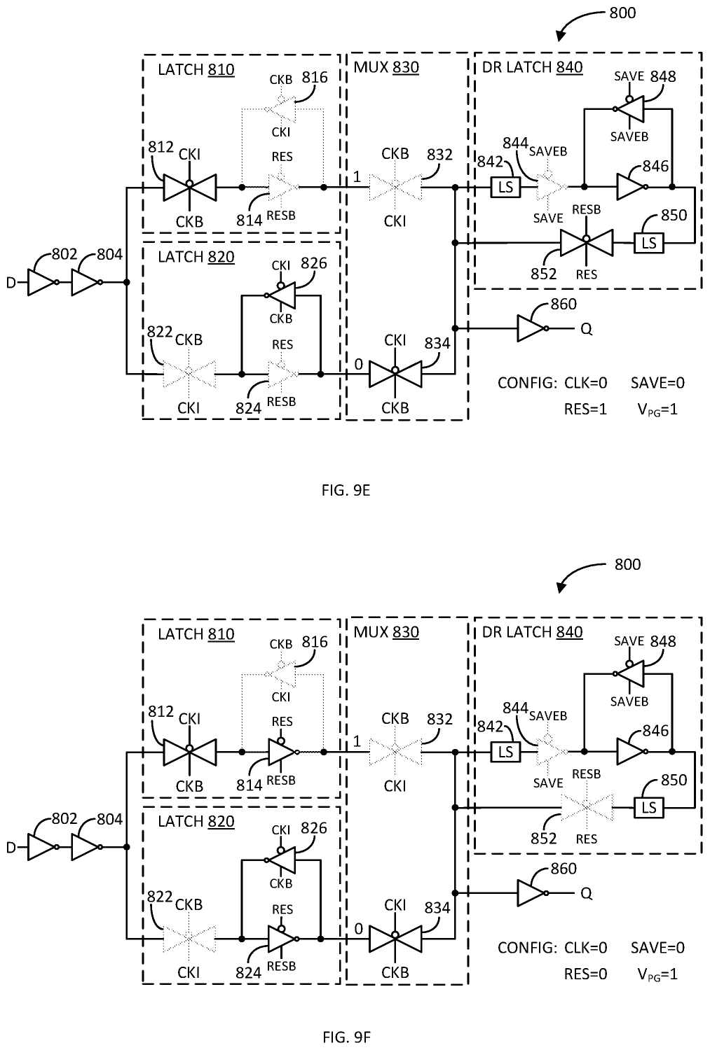

FIGS. 9A-9F illustrate the example DET FF 800 in various configurations pursuant to a save and restore data retention operation in accordance with another aspect of the disclosure. In these figures, the lightly-shaded components are disabled and the normal shaded components are enabled.

With specific reference to FIG. 9A, the second latch 820 is in opaque configuration (e.g., CLK=0) and storing the output data Q (albeit, inverted) for data retention purposes. Accordingly, the tristate inverter 816 of the first latch 810 and the transmission gate 822 of the second latch 820 are disabled. Also, in this configuration, the restore signal RES is deasserted (e.g., RES=0). Accordingly, the transmission gate 852 is disabled. The supply voltage V_{PG} is present (e.g., V_{PG}=1). The storing operation commences with the save signal SAVE being asserted (e.g., SAVE=1). In this configuration, the DR latch 840 is transparent, e.g., so that the enabled tristate inverter 844 routes the data stored by the second latch 820 to the disabled cross-coupled inverter 846 and tristate inverter 848.

With specific reference to FIG. 9B, then according to the storing operation, the save signal SAVE becomes deasserted (e.g., SAVE=0). Thus, the DR latch 840 becomes opaque, e.g., the tristate inverter 844 is disabled, and the cross-coupled inverter 846 and tristate inverter 848 is enabled to latch the data. Once that occurs, the power gating interval may commence by removing the supply voltage V_{PG} (e.g., V_{PG}=0).

With specific reference to FIG. 9C, the supply voltage V_{PG} (e.g., V_{PG}=1) may then be provided to end the power gating interval, and then the restore signal RES may be asserted (e.g., RES=1) to commence the restoring operation. The assertion of the restore signal RES disables the tristate inverters 814 and 824, and enables the transmission gate 852. In this example, the end of the power gating interval and the assertion of the restore signal RES occurs during the high phase (e.g., CLK=1) of the clock signal CLK. In such case, the first latch 810 is transparent in the reverse direction (e.g., from the DR latch 840 to the first latch 810). Thus, the first latch 810 receives the retained data from the DR latch 840 via the enabled transmission gates 852 and 832.

With specific reference to FIG. 9D, the restore operation is terminated with the deassertion of the restore signal RES (e.g., RES=1). In response, the first latch 810 becomes opaque to store the previously retained data, which, as discussed is the data, albeit inverted, at the output Q of the DET FF 800. Note that in this example, the retained data originated from the second latch 820 during the store operation, and ended up at the first latch 810 during the restore operation. Thus, the DET FF 800 may perform the data retention operation independent of the phase of the clock signal CLK, in contrast to the DET FF 600 previously discussed.

For the sake of completeness, instead of the restore operation commencing during the high phase of the clock signal CLK as indicated in FIG. 9C, the restore operation may commence during the low phase of the clock signal. In this regard, with specific reference to FIG. 9E, the supply voltage V_{PG} (e.g., V_{PG}=1) may then be provided to end the power gating interval, and then the restore signal RES may be asserted (e.g., RES=1) to commence the restoring operation. The assertion of the restore signal RES disables the tristate inverters 814 and 824, and enables the transmission gate 852. In this case, the second latch 820 is transparent in the reverse direction (e.g., from the DR latch 840 to the second latch 820). Thus, the second latch 820 receives the retained data from the DR latch 840 via the enabled transmission gates 852 and 834.

With specific reference to FIG. 9F, the restore operation is terminated with the deassertion of the restore signal RES (e.g., RES=1). In response, the second latch 820 becomes opaque to store the previously retained data, which, as discussed is the data, albeit inverted, at the output Q of the DET FF 800. Note that in this case, the retained data originated from and ended up at the second latch 820 during the store and restore operations. This is reaffirmation that the DET FF 800 may perform the data retention operation independent of the phase of the clock signal CLK, in contrast to the DET FF 600 previously discussed.

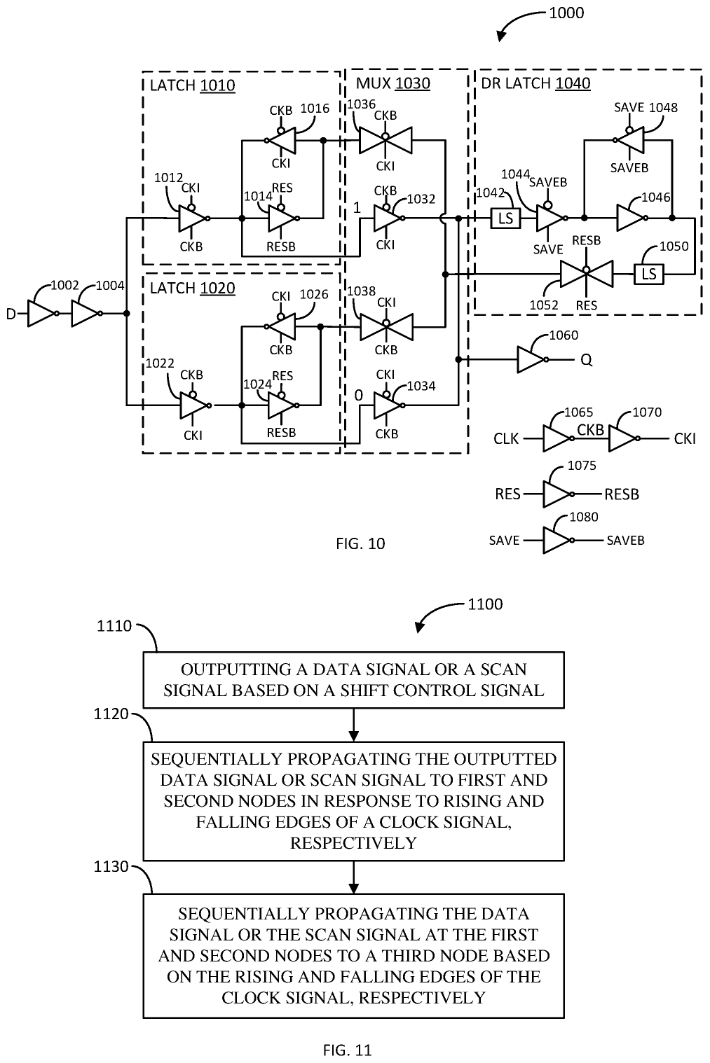

FIG. 10 illustrates a block diagram of another example dual-edge-triggered (DET) flip-flop (FF) 1000 including a data retention feature in accordance with another aspect of the disclosure. The DET FF 1000 may be an example implementation of DET FF 700, and a variation of DET FF 800, where DET FF 1000 is based on DET FF 400, whereas DET FF 800 is based on the DET FF 300. In particular, the DET FF 1000 includes a buffer including one or more cascaded inverters 1002 and 1004, a first latch 1010, a second latch 1020, an output multiplexer 1030, and a data retention (DR) latch 1040. The buffer 1002/1004 is coupled between a data (D) input and the inputs of the first and second latches 1010 and 1020.

The first latch 1010 includes a first tristate inverter 1012, and a second tristate inverter 1014 cross-coupled with a third tristate inverter 1016. The first tristate inverter 1012 includes a complementary input configured to receive a clock signal CKI, and a non-complementary input configured to receive a complementary clock signal CKB. The DET FF 1000 includes a clock generation circuit including cascaded inverters 1065 and 1070 configured to generate the complementary clock signal CKB and the clock signal CKI based on an input clock signal CLK, respectively. The second tristate inverter 1014 includes a complementary input configured to receive a restore (RES) signal and a non-complementary input configured to receive a complementary restore signal RESB. The DET FF 1000 includes at least one inverter 1075 configured to generate the complementary restore signal RESB from the restore signal RES. The tristate inverter 1016 includes a complementary input configured to receive the complementary clock signal CKB, and a non-complementary input configured to receive the clock signal CKI. The tristate inverter 1012 is coupled between the input and output of the first latch 1010.

The second latch 1020 includes a first tristate inverter 1022, and a second tristate inverter 1024 cross-coupled with a third tristate inverter 1026. The first tristate inverter 1022 includes a complementary input configured to receive the complementary clock signal CKB, and a non-complementary input configured to receive the clock signal CKI. The tristate inverter 1024 includes a complementary input configured to receive the restore signal RES and a non-complementary input configured to receive the complementary restore signal RESB. The tristate inverter 1026 includes a complementary input configured to receive the clock signal CKI, and a non-complementary input configured to receive the complementary clock signal CKB. The first tristate inverter 1022 is coupled between the input and output of the second latch 1020.

The multiplexer 1020 includes inputs “1” and “0” coupled to the outputs of the first and second latches 1010 and 1020, respectively. The multiplexer 1020 includes first and second tristate inverter 1032 and 1034 coupled between the first “1” and second “0” inputs and the output of the multiplexer 1030, respectively. The multiplexer 1030 further includes a first transmission gate 1036 coupled between an output of the DR latch 1040 and the cross-coupled tristate inverters 1014 and 1016. The first transmission gate 1036 includes a complementary input configured to receive the complementary clock signal CKB, and a non-complementary input configured to receive the clock signal CKI. Similarly, the multiplexer 1030 further includes a second transmission gate 1038 coupled between the output of the DR latch 1040 and the cross-coupled tristate inverters 1024 and 1026. The second transmission gate 1038 includes a complementary input configured to receive the clock signal CKI, and a non-complementary input configured to receive the complementary clock signal CKB.

The DR latch 1020 includes a first level shifter (LS) 1042, a first tristate inverter 1044, an inverter 1046 cross-coupled with a second tristate inverter 1048, a second LS 1050, and a transmission gate 1052 coupled in series between the output of the multiplexer 1030 and inputs of the transmission gates 1036 and 1038. The first LS 1042, including an input coupled to the output of the multiplexer 1030, is configured to provide buffering/isolation and/or voltage level shifting between the output of the multiplexer 1030 and the tristate inverter 1044 as they may be on different voltage domains V_{PG} and V_{AON}, respectively. The tristate inverter 1044 includes an input coupled to an output of the first LS 1042, a complementary input configured to receive a complementary save signal SAVEB, and a non-complementary input configured to receive the save signal SAVE. In this regard, the DR latch 1020 includes at least one inverter 1080 configured to generate the complementary save signal SAVEB from the save signal SAVE.

The cross-coupled inverter 1046 and second tristate inverter 1048 are coupled between an output of the tristate inverter 1044 and an input of the second LS 1050. The second tristate inverter 1048 includes a complementary input configured to receive the save signal SAVE, and a non-complementary input configured to receive the complementary save signal SAVEB. The second LS 1050 also provides buffering/isolation and/or voltage level shifting between the cross-coupled inverter 1046 and second tristate inverter 1048 and the transmission gate 1052 as they may be on different voltage domains V_{AON} and V_{PG}, respectively. The transmission gate 1052, which is coupled between the second LS 1050 and the inputs of the transmission gates 1036 and 1038, includes a complementary input configured to receive the complementary restore signal RESB and a non-complementary input configured to receive the restore signal RES.

As alluded to, the buffer 1002/1004, the first latch 1010, the second latch 1020, the multiplexer 1030, the clock generating inverters 1065 and 1070, the restore signal related inverter 1075, the second LS 1050, and the transmission gate 1052 may be in the V_{PG} voltage domain. Whereas, the first LS 1042, the first tristate inverter 1044, the cross-coupled inverter 1046 and second tristate inverter 1048, and the save signal related inverter 1080 may be in the V_{AON} voltage domain.

The save and restore operations of DET FF 1000 operate similar to that of DET FF 800. Briefly, during a save operation (V_{PG}=1, SAVE=1, RES=0), the first or second latch 1010 in opaque configuration provides the output data (e.g., inverted twice via tristate inverter 1032 or 1034 and inverter 1060) to the transparent DR latch 1040. The power gating interval may then commence (V_{PG}=0, SAVE=0, RES=0) with the deassertion of the save signal SAVE setting the DR latch 1040 in opaque configuration. Then power gating interval may then end (V_{PG}=1, SAVE=0, RES=1) with the transmission gate 1036 or 1034 providing the transparent first or second latch in the reverse direction with the retained data from the DR latch 1040. Then the restore operation is complete (V_{PG}=1, SAVE=0, RES=0) with the deassertion of the restore signal RES causing the first or second latch 1010 or 1020 becoming opaque based on the phase of the clock signal CLK (e.g., first latch 1010 becomes opaque if CLK=1, or second latch 1020 becomes opaque if CLK=0). The opaque latch 1010 or 1020 ensures the data at the output Q is stable.

FIG. 11 illustrates a flow diagram of an example method 1100 of propagating a selected data or scan signal in accordance with another aspect of the disclosure. The method 1100 includes outputting a data signal or a scan signal based on a shift control signal (block 1110). Examples of means for outputting a data signal or a scan signal based on a shift control signal include any of the multiplexers 210, 310, and 410 described herein.

The method 1100 further includes sequentially propagating the outputted data signal or scan signal to first and second nodes in response to rising and falling edges of a clock signal, respectively (block 1120). Examples of means for sequentially propagating the outputted data signal or scan signal to first and second nodes in response to rising and falling edges of a clock signal, respectively, include any of the first and second latches described herein.

Additionally, the method 1100 includes sequentially propagating the data signal or the scan signal at the first and second nodes to a third node based on the rising and falling edges of the clock signal, respectively (block 1130). Examples of means for sequentially propagating the data signal or the scan signal at the first and second nodes to a third node based on the rising and falling edges of the clock signal, respectively, include any of the multiplexers 240, 340, 440, 630, 730, 830, and 1030 described herein.

The method 1100 may further include setting the first and second nodes to known values in response to a reset signal. Examples of means for setting the first and second nodes to known values in response to a reset signal include any of the circuitry responsive to the reset signal described herein.

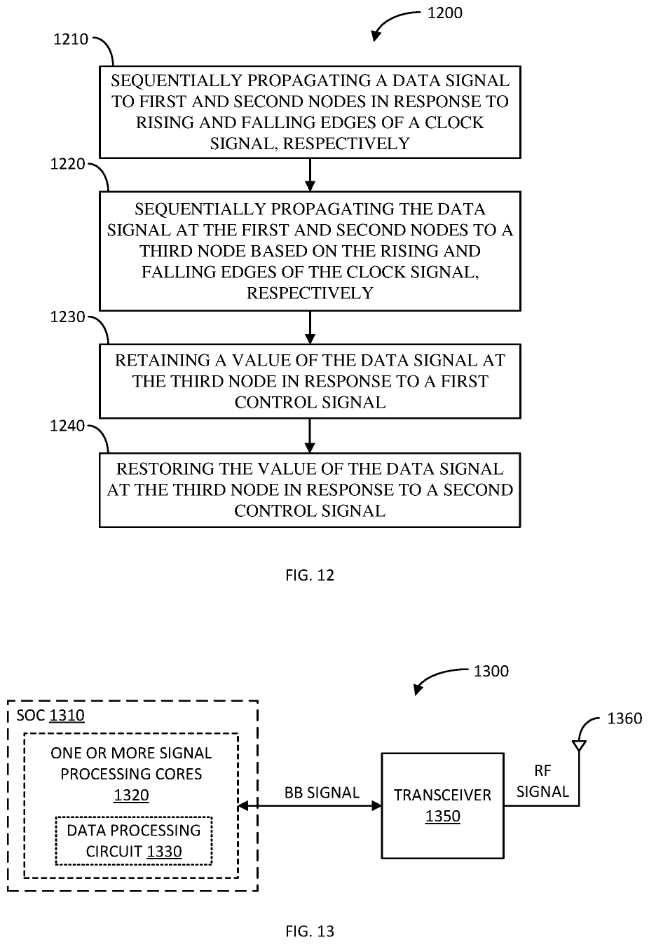

FIG. 12 illustrates a flow diagram of an example method 1200 of retaining and restoring a value of a data signal at an output of a dual-edge-triggered (DET) flip-flop (FF) in accordance with another aspect of the disclosure. The method 1200 includes sequentially propagating a data signal to first and second nodes in response to rising and falling edges of a clock signal, respectively (block 1210). Examples of means for sequentially propagating a data signal to first and second nodes in response to rising and falling edges of a clock signal include any of the first and second latches described herein.

The method 1200 further includes sequentially propagating the data signal at the first and second nodes to a third node based on the rising and falling edges of the clock signal, respectively (block 1220). Examples of means for sequentially propagating the data signal at the first and second nodes to a third node based on the rising and falling edges of the clock signal, respectively, include any of the multiplexers 240, 340, 440, 630, 730, 830, and 1030 described herein.

Additionally, the method 1200 includes retaining a value of the data signal at the third node in response to a first control signal (block 1230). Examples of means for retaining a value of the data signal at the third node in response to a first control signal include any of the DR latches described herein. Further, the method 1200 includes restoring the value of the data signal at the third node in response to a second control signal (block 1240). Examples of means for restoring the value of the data signal at the third node in response to a second control signal include any of the DR latches described herein.

FIG. 13 illustrates a block diagram of an example wireless communication device 1300 in accordance with another aspect of the disclosure. The wireless communication device 1300 may be a smart phone, a desktop computer, laptop computer, tablet device, Internet of Things (IoT), wearable wireless device (e.g., wireless watch), and other types of wireless device.

In particular, the wireless communication device 1300 includes an integrated circuit (IC), which may be implemented as a system on chip (SOC) 1310. The SOC 1310 includes one or more signal processing cores 1320, and one or more clock gating circuits (CGCs) 1330. The one or more signal processing cores 1320 may be configured to generate a transmit baseband (BB) signal and process a received baseband (BB) signal based on one or more clock signals received from the one or more CGCs 1330. The one or more signal processing cores 1320 may include any combination of the data processing circuit 100 or 200, including any combination of the DET FFs described herein to generate and process the transmit and receive BB signals, respectively.

The wireless communication device 1300 may further include a transceiver 1350 and at least one antenna 1360 (e.g., an antenna array). The transceiver 1350 is coupled to the one or more signal processing cores 1320 to receive therefrom the transmit BB signal and provide thereto the received BB signal. The transceiver 1350 is configured to convert the transmit BB signal into a transmit radio frequency (RF) signal, and convert a received RF signal into the received BB signal. The transceiver 1350 is coupled to the at least one antenna 1360 to provide thereto the transmit RF signal for electromagnetic radiation into a wireless medium for wireless transmission, and receive the received RF signal electromagnetically picked up from the wireless medium by the at least one antenna 1360.

The following provides an overview of aspects of the present disclosure:

Aspect 1: An apparatus, comprising: a first multiplexer including inputs configured to receive an input data signal and a scan signal, and a select input configured to receive shift control signal; a first latch including an input coupled to an output of the first multiplexer, and a complementary clock input configured to receive a clock signal; a second latch including an input coupled to the output of the first multiplexer, and a non-complementary clock input configured to receive the clock signal; and a second multiplexer including inputs coupled to outputs of the first and second latches, respectively, a select input configured to receive the clock signal, and an output configured to generate an output data or scan signal.

Aspect 2: The apparatus of aspect 1, wherein the first multiplexer comprises: first, second, third, and fourth field effect transistors (FETs) coupled in series between an upper voltage rail and a lower voltage rail, wherein the first FET includes a gate configured to receive the shift control signal, the second and third FETs include gates configured to receive the input data signal, and the fourth FET includes a gate configured to receive a complementary shift control signal; and fifth, sixth, seventh, and eighth FETs coupled in series between the upper voltage rail and the lower voltage rail, wherein the fifth and eighth FETs include gates configured to receive the scan signal, the sixth FET includes a gate configured to receive the complementary shift control signal, and the seventh FET includes a gate configured to receive the shift control signal.

Aspect 3: The apparatus of aspect 2, wherein the first, second, fifth, and sixth FETs are implemented as p-channel FETs, and the third, fourth, seventh, and eighth FETs are implemented as n-channel FETs.

Aspect 4: The apparatus of any one of aspects 1-3, wherein the first latch comprises: a first gating circuit configured to receive the clock signal; a first inverter coupled to the first gating circuit; and a first tristate inverter cross-coupled with the first inverter, wherein the first tristate inverter is configured to receive the clock signal.

Aspect 5: The apparatus of aspect 4, wherein the first gating circuit comprises a transmission gate.

Aspect 6: The apparatus of aspect 4, wherein the first gating circuit comprises a second tristate inverter.

Aspect 7: The apparatus of aspect 6, wherein the second tristate inverter comprises first, second, third, and fourth field effect transistors (FETs) coupled in series between an upper voltage rail and a lower voltage rail, wherein the first FET includes a gate configured to receive the clock signal, the second and third FETs include gates coupled to the output of the first multiplexer, and the fourth FET includes a gate configured to receive a complementary clock signal.

Aspect 8: The apparatus of aspect 7, wherein the first and second FETs are implemented as p-channel FETs, and the third and fourth FETs are implemented as n-channel FETs.

Aspect 9: The apparatus of any one of aspects 4-8, wherein the first tristate inverter comprises first, second, third, and fourth FETs coupled in series between an upper voltage rail and a lower voltage rail, wherein the first and fourth FETs include gates coupled to an output of the first inverter, the second FET includes a gate configured to receive a complementary clock signal, the third FET includes a gate configured to receive the clock signal, and a node between the second and third FETs is coupled to an input of the first inverter.

Aspect 10: The apparatus of aspect 9, wherein the first and second FETs are implemented as p-channel FETs, and the third and fourth FETs are implemented as n-channel FETs.

Aspect 11: The apparatus of any one of aspects 4-10, wherein the second latch comprises: a second gating circuit; a second inverter coupled to the second gating circuit; and a second tristate inverter cross-coupled with the second inverter, wherein the second tristate inverter is configured to receive the clock signal.

Aspect 12: The apparatus of any one of aspects 1-11, wherein the second multiplexer comprises: a first gating circuit coupled between the output of the first latch and the output of the second multiplexer; and a second gating circuit coupled between the output of the second latch and the output of the second multiplexer.

Aspect 13: The apparatus of aspect 12, wherein at least one of the first gating circuit or the second gating circuit comprises a transmission gate.

Aspect 14: The apparatus of aspect 12 or 13, wherein at least one of the first gating circuit or the second gating circuit comprises a tristate inverter.

Aspect 15: The apparatus of any one of aspects 1-14, further comprising an inverter coupled to the output of the second multiplexer, wherein the second multiplexer is configured to generate the output data or scan signal at an output of the inverter.

Aspect 16: The apparatus of any one of aspects 1-15, wherein the first and second DETs are configured to generate a known value at each of the outputs of the first and second DETs in response to a reset signal.

Aspect 17: The apparatus of aspect 16, wherein the first latch comprises: a first gating circuit configured to receive the clock signal; a first inverter coupled to the first gating circuit; and a first tristate inverter cross-coupled with the first inverter, wherein the first tristate inverter is configured to receive the clock signal and the reset signal.

Aspect 18: The apparatus of aspect 17, wherein the first gating circuit comprises a transmission gate.

Aspect 19: The apparatus of aspect 18, further comprising a voltage contention prevention inverter circuit coupled between the output of the first multiplexer and the transmission gate, wherein the voltage content circuit is configured to receive the reset signal.

Aspect 20: The apparatus of aspect 19, wherein the voltage content circuit comprises first, second, and third field effect transistors (FETs) coupled in series between the upper voltage rail and the lower voltage rail, wherein the first FET includes a gate configured to receive the reset signal, wherein the second and third FETs include gates coupled to the output of the first multiplexer, and wherein a node between the second and third FETs is coupled to the transmission gate.

Aspect 21: The apparatus of aspect 20, wherein the first and second FETs are implemented as p-channel FETs, and the third FET is implemented as an n-channel FET.

Aspect 22: The apparatus of aspect 17, wherein the first gating circuit is further configured to receive the reset signal.

Aspect 23: The apparatus of aspect 22, wherein the first gating circuit comprises a second tristate inverter.

Aspect 24: The apparatus of any one of aspects 17 and 22-23, wherein the first tristate inverter comprises: first, second, third, and fourth FETs coupled in series between an upper voltage rail and a lower voltage rail, wherein the first and fourth FETs include gates coupled to the output of the first inverter, the second FET include a gate configured to receive a complementary clock signal, the third FET includes a gate configured to receive the clock signal, and a node between the second and third FETs is coupled to an input of the first inverter.

Aspect 25: The apparatus of aspect 24, wherein the first and second FETs are implemented as p-channel FETs, and the third and fourth FETs are implemented as n-channel FETs.

Aspect 26: The apparatus of any one of aspects 22-25, wherein the second tristate inverter comprises: first, second, third, fourth, and fifth FETs coupled in series between an upper voltage rail and a lower voltage rail, wherein the first FET includes a gate configured to receive the reset signal, the second FET is configured to receive the clock signal, the third and fourth FETs include gates coupled to the output of the first multiplexer, the fifth FET includes a gate configured to receive a complementary clock signal, and a node between the third and fourth FETs is coupled to an input of the first inverter; and a sixth FET coupled between the node and the lower voltage rail, wherein the sixth FET includes a gate configured to receive the reset signal.

Aspect 27: The apparatus of aspect 26, wherein the first, second, and third FETs are implemented as p-channel FETs, and the fourth, fifth, and sixth FETs are implemented as n-channel FETs.

Aspect 28: The apparatus of an one of aspects 17-21, wherein the first tristate inverter comprises: first, second, third, fourth, and fifth FETs coupled in series between an upper voltage rail and the lower voltage rail, wherein the first FET includes a gate configured to receive the reset signal, the second and fifth FETs include gates coupled to an output of the first inverter, the third FET includes a gate configured to receive a complementary clock signal, the fourth FET includes a gate configured to receive the clock signal, and a node between the third and fourth FETs is coupled to an input of the first inverter; and a sixth FET coupled between the node and the lower voltage rail, wherein the sixth FET includes a gate configured to receive the reset signal.

Aspect 29: The apparatus of aspect 28, wherein the first, second, and third FETs are implemented as p-channel FETs, and the fourth, fifth, and sixth FETs are implemented as n-channel FETs.

Aspect 30: The apparatus of any one of aspects 17-21, wherein the second comprises: a second gating circuit configured to receive the clock signal; a second inverter coupled to the second gating circuit; and a second tristate inverter cross-coupled with the second inverter, wherein the second tristate inverter is configured to receive the clock signal and the reset signal.

Aspect 31: A method, comprising: outputting a data signal or a scan signal based on a shift control signal; sequentially propagating the outputted data signal or scan signal to first and second nodes in response to rising and falling edges of a clock signal, respectively; and sequentially propagating the data signal or the scan signal at the first and second nodes to a third node based on the rising and falling edges of the clock signal, respectively.

Aspect 32: The method of aspect 31, further comprising setting the first and second nodes to known values in response to a reset signal.

Aspect 33: An apparatus, comprising: means for outputting a data signal or a scan signal based on a shift control signal; means for sequentially propagating the outputted data signal or scan signal to first and second nodes in response to rising and falling edges of a clock signal; and means for sequentially propagating the data signal or the scan signal at the first and second nodes to a third node based on the rising and falling edges of the clock signal, respectively.

Aspect 34: The apparatus of aspect 33, further comprising means for setting the first and second nodes to known values in response to a reset signal.

Aspect 35: A wireless communication device, comprising: at least one antenna; a transceiver coupled to the at least one antenna; and one or more signal processing cores coupled to the transceiver, wherein the one or more signal processing core comprise: a first multiplexer including inputs configured to receive an input data signal and a scan signal, and a select input configured to receive shift control signal; a first latch including an input coupled to an output of the first multiplexer, and a complementary clock input configured to receive a clock signal; a second latch including an input coupled to the output of the first multiplexer, and a non-complementary clock input configured to receive the clock signal; and a second multiplexer including inputs coupled to outputs of the first and second DETs, respectively, a select input configured to receive the clock signal, and an output configured to generate an output data signal.

Aspect 36: An apparatus, comprising: a first latch including an input configured to receive an input data signal, and a complementary clock input configured to receive a clock signal; a second latch including an input configured to receive the input data signal, and a non-complementary clock input configured to receive the clock signal; a multiplexer including inputs coupled to outputs of the first and second latch, respectively, and an output configured to generate an output data signal; and a first data retention (DR) latch configured to: store a value of the output data signal at the output of the multiplexer in response to a first control signal; and restore the value of the output data signal to the output of the multiplexer in response to a second control signal.

Aspect 37: The apparatus of aspect 36, wherein the first DR latch is coupled to the output of the multiplexer.

Aspect 38: The apparatus of aspect 36 or 37, wherein at least one of the first latch or the second latch comprises: a first tristate inverter configured to receive the clock signal; and a second tristate inverter cross-coupled with the first tristate inverter between first and second nodes, wherein the second tristate inverter is configured to receive the second control signal.

Aspect 39: The apparatus of aspect 38, wherein the multiplexer comprises: a third tristate inverter including an input coupled to the first node and an output coupled to an input of the first DR latch, wherein the third tristate inverter is configured to receive the clock signal; and a gating circuit coupled between an output of the first DR latch and the second node, wherein the transmission gate is configured to receive the clock signal.

Aspect 40: The apparatus of aspect 36, wherein the first DR latch comprises: a first tristate inverter including an input coupled to the output of the multiplexer, wherein the first tristate inverter is configured to receive the first control signal; an inverter including an input coupled to an output of the first tristate inverter; a second tristate inverter cross-coupled with the inverter, wherein the second tristate inverter is configured to receive the first control signal; and a transmission gate coupled between the cross-coupled first and second tristate inverters and the output of the multiplexer.

Aspect 41: The apparatus of aspect 36, wherein the first DR latch is coupled to the output of the first latch, and further comprising a second DR latch coupled to the output of the second latch, wherein the second DR latch is configured to: store another value of the output data signal at the output of the multiplexer in response to the first control signal; and restore the another value of the output data signal to the output of the multiplexer in response to the second control signal.

Aspect 42: A method, comprising: sequentially propagating a data signal to first and second nodes in response to rising and falling edges of a clock signal, respectively; sequentially propagating the data signal at the first and second nodes to a third node based on the rising and falling edges of the clock signal, respectively; retaining a value of the data signal at the third node in response to a first control signal; and restoring the value of the data signal at the third node in response to a second control signal.

Aspect 43: An apparatus, comprising: means for sequentially propagating a data signal to first and second nodes in response to rising and falling edges of a clock signal, respectively; means for sequentially propagating the data signal at the first and second nodes to a third node based on the rising and falling edges of the clock signal, respectively; means for retaining a value of the data signal at the third node in response to a first control signal; and means for restoring the value of the data signal at the third node in response to a second control signal.

Aspect 44: A wireless communication device, comprising: at least one antenna; a transceiver coupled to the at least one antenna; and one or more signal processing cores coupled to the transceiver, wherein the one or more signal processing core comprise: a first latch including an input configured to receive an input data signal, and a complementary clock input configured to receive a clock signal; a second latch including an input configured to receive the input data signal, and a non-complementary clock input configured to receive the clock signal; a multiplexer including inputs coupled to outputs of the first and second latch, respectively, and an output configured to generate an output data signal; and a first data retention (DR) latch configured to: store a value of the output data signal at the output of the multiplexer in response to a first control signal; and restore the value of the output data signal to the output of the multiplexer in response to a second control signal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An apparatus, comprising:
a first multiplexer including inputs configured to receive an input data signal and a scan signal, and a select input configured to receive shift control signal;
a first latch including an input coupled to an output of the first multiplexer, and a complementary clock input configured to receive a clock signal;
a second latch including an input coupled to the output of the first multiplexer, and a non-complementary clock input configured to receive the clock signal; and
a second multiplexer including inputs coupled to outputs of the first and second latches, respectively, a select input configured to receive the clock signal, and an output configured to generate an output data or scan signal.

2. The apparatus of claim 1, wherein the first multiplexer comprises:
first, second, third, and fourth field effect transistors (FETs) coupled in series between an upper voltage rail and a lower voltage rail, wherein the first FET includes a gate configured to receive the shift control signal, the second and third FETs include gates configured to receive the input data signal, and the fourth FET includes a gate configured to receive a complementary shift control signal; and
fifth, sixth, seventh, and eighth FETs coupled in series between the upper voltage rail and the lower voltage rail, wherein the fifth and eighth FETs include gates configured to receive the scan signal, the sixth FET includes a gate configured to receive the complementary shift control signal, and the seventh FET includes a gate configured to receive the shift control signal.

3. The apparatus of claim 1, wherein the first latch comprises:
a first gating circuit configured to receive the clock signal;
a first inverter coupled to the first gating circuit; and
a first tristate inverter cross-coupled with the first inverter, wherein the first tristate inverter is configured to receive the clock signal.

4. The apparatus of claim 3, wherein the first gating circuit comprises a transmission gate.

5. The apparatus of claim 3, wherein the first gating circuit comprises a second tristate inverter.

6. The apparatus of claim 5, wherein the second tristate inverter comprises first, second, third, and fourth field effect transistors (FETs) coupled in series between an upper voltage rail and a lower voltage rail, wherein the first FET includes a gate configured to receive the clock signal, the second and third FETs include gates coupled to the output of the first multiplexer, and the fourth FET includes a gate configured to receive a complementary clock signal.

7. The apparatus of claim 3, wherein the first tristate inverter comprises first, second, third, and fourth FETs coupled in series between an upper voltage rail and a lower voltage rail, wherein the first and fourth FETs include gates coupled to an output of the first inverter, the second FET includes a gate configured to receive a complementary clock signal, the third FET includes a gate configured to receive the clock signal, and a node between the second and third FETs is coupled to an input of the first inverter.

8. The apparatus of claim 3, wherein the second latch comprises:
a second gating circuit;
a second inverter coupled to the second gating circuit; and
a second tristate inverter cross-coupled with the second inverter, wherein the second tristate inverter is configured to receive the clock signal.

9. The apparatus of claim 1, wherein the second multiplexer comprises:
a first gating circuit coupled between the output of the first latch and the output of the second multiplexer; and
a second gating circuit coupled between the output of the second latch and the output of the second multiplexer.

10. The apparatus of claim 9, wherein at least one of the first gating circuit or the second gating circuit comprises a transmission gate.

11. The apparatus of claim 9, wherein at least one of the first gating circuit or the second gating circuit comprises a tristate inverter.

12. The apparatus of claim 1, wherein the first and second latches are configured to generate a known value at each of the outputs of the first and second latches in response to a reset signal.

13. The apparatus of claim 12, wherein the first latch comprises:
a first gating circuit configured to receive the clock signal;
a first inverter coupled to the first gating circuit; and
a first tristate inverter cross-coupled with the first inverter, wherein the first tristate inverter is configured to receive the clock signal and the reset signal.

14. The apparatus of claim 13, wherein the first gating circuit comprises a transmission gate.

15. The apparatus of claim 14, further comprising a voltage contention prevention inverter circuit coupled between the output of the first multiplexer and the transmission gate, wherein the voltage content circuit is configured to receive the reset signal.

16. The apparatus of claim 15, wherein the voltage contention prevention inverter circuit comprises first, second, and third field effect transistors (FETs) coupled in series between an upper voltage rail and a lower voltage rail, wherein the first FET includes a gate configured to receive the reset signal, wherein the second and third FETs include gates coupled to the output of the first multiplexer, and wherein a node between the second and third FETs is coupled to the transmission gate.

17. The apparatus of claim 13, wherein the first gating circuit is further configured to receive the reset signal.

18. The apparatus of claim 13, wherein the first gating circuit comprises a second tristate inverter.

19. The apparatus of claim 18, wherein the second tristate inverter comprises:
first, second, third, fourth, and fifth FETs coupled in series between an upper voltage rail and a lower voltage rail, wherein the first FET includes a gate configured to receive the reset signal, the second FET is configured to receive the clock signal, the third and fourth FETs include gates coupled to the output of the first multiplexer, the fifth FET includes a gate configured to receive a complementary clock signal, and a node between the third and fourth FETs is coupled to an input of the first inverter; and
a sixth FET coupled between the node and the lower voltage rail, wherein the sixth FET includes a gate configured to receive the reset signal.

20. The apparatus of claim 13, wherein the first tristate inverter comprises:
first, second, third, fourth, and fifth FETs coupled in series between the upper voltage rail and the lower voltage rail, wherein the first FET includes a gate configured to receive the reset signal, the second and fifth FETs include gates coupled to an output of the first inverter, the third FET includes a gate configured to receive a complementary clock signal, the fourth FET includes a gate configured to receive the clock signal, and a node between the third and fourth FETs is coupled to an input of the first inverter; and
a sixth FET coupled between the node and the lower voltage rail, wherein the sixth FET includes a gate configured to receive the reset signal.

21. The apparatus of claim 13, wherein the second latch comprises:
a second gating circuit configured to receive the clock signal;
a second inverter coupled to the second gating circuit; and
a second tristate inverter cross-coupled with the second inverter, wherein the second tristate inverter is configured to receive the clock signal and the reset signal.

22. A method, comprising:
outputting a data signal or a scan signal based on a shift control signal;
sequentially propagating the outputted data signal or scan signal to first and second nodes in response to rising and falling edges of a clock signal, respectively; and
sequentially propagating the data signal or the scan signal at the first and second nodes to a third node based on the rising and falling edges of the clock signal, respectively.

23. The method of claim 22, further comprising setting the first and second nodes to known values in response to a reset signal.

24. An apparatus, comprising:
a first latch including an input configured to receive an input data signal, and a clock input configured to receive a complementary clock signal;
a second latch including an input configured to receive the input data signal, and a clock input configured to receive a non-complementary clock signal;
a multiplexer including inputs coupled to outputs of the first and second latches, respectively, and an output configured to generate an output data signal; and
a first data retention (DR) latch configured to:
store a value of the output data signal at the output of the multiplexer in response to a first control signal; and
restore the value of the output data signal to the output of the multiplexer in response to a second control signal.

25. The apparatus of claim 24, wherein the first DR latch is coupled to the output of the multiplexer.

26. The apparatus of claim 24, wherein at least one of the first latch or the second latch comprises:
a first tristate inverter configured to receive the clock signal; and
a second tristate inverter cross-coupled with the first tristate inverter between first and second nodes, wherein the second tristate inverter is configured to receive the second control signal.

27. The apparatus of claim 26, wherein the multiplexer comprises:
a third tristate inverter including an input coupled to the first node and an input of the first DR latch, wherein the third tristate inverter is configured to receive the clock signal; and
a transmission gate coupled between an output of the first DR latch and the second node, wherein the transmission gate is configured to receive the clock signal.

28. The apparatus of claim 24, wherein the first DR latch comprises:
a first tristate inverter including an input coupled to the output of the multiplexer, wherein the first tristate inverter is configured to receive the first control signal;
an inverter including an input coupled to an output of the first tristate inverter;
a second tristate inverter cross-coupled with the inverter, wherein the second tristate inverter is configured to receive the first control signal; and
a transmission gate coupled between the cross-coupled first and second tristate inverters and the output of the multiplexer, wherein the transmission gate is configured to receive the second control signal.

29. The apparatus of claim 24, wherein the first DR latch is coupled to the output of the first latch, and further comprising a second DR latch coupled to the output of the second latch, wherein the second DR latch is configured to:
store another value of the output data signal at the output of the multiplexer in response to the first control signal; and
restore the another value of the output data signal to the output of the multiplexer in response to the second control signal.

30. A method, comprising:
sequentially propagating a data signal to first and second nodes in response to rising and falling edges of a clock signal, respectively;
sequentially propagating the data signal at the first and second nodes to a third node based on the rising and falling edges of the clock signal, respectively;
retaining a value of the data signal at the third node in response to a first control signal; and
restoring the value of the data signal at the third node in response to a second control signal.
